(19) United States
(12) Patent Application Publication
(10) Pub. No.: US 2026/0162706 A1
(43) Pub. Date: Jun. 11, 2026

(54) MEMORY DEVICE PERFORMING REFRESH OPERATION AND OPERATING METHOD THEREOF

(71) Applicant: SK hynix Inc., Gyeonggi-do (KR)

(72) Inventor: Jung Ho LIM, Gyeonggi-do (KR)

(21) Appl. No.: 19/098,930

(22) Filed: Apr. 2, 2025

(30) Foreign Application Priority Data
Dec. 10, 2024 (KR) 10-2024-0182324

(51) Int. Cl. G11C 11/406

(52) U.S. Cl. CPC G11C 11/40618

(57) ABSTRACT

A memory device includes first to n-th banks, where n is a positive integer of 2 or more; a storage circuit configured to store first voltage information representing a voltage condition during an active operation and second voltage information representing a voltage condition during a refresh operation; and a sensing control circuit configured to select one of the first voltage information and the second voltage information according to a refresh section signal and a bank selection signal designating a k-th bank, where k is an integer equal to or less than n, among the first to n-th banks, and control a sensing timing for each of the first to n-th banks based on the selected voltage information.

### CROSS-REFERENCE TO RELATED APPLICATION

The present application claims priority under 35 U.S.C 119(a) to Korean Patent Application No. 10-2024-0182324, filed on Dec. 10, 2024, which is incorporated herein by reference in its entirety.

### BACKGROUND

### 1. Field

Various embodiments of the present disclosure relate to a semiconductor design technology, and more particularly, to a memory device performing an all-bank refresh operation.

### 2. Description of the Related Art

A memory device such as a dynamic random access memory (DRAM) may include a memory cell array for storing data. Generally, since arrangement of the memory cell array is implemented as a lattice divided into rows and columns, it is possible to access cells to read or write data by designating a row address and a column address. The DRAM may include a plurality of memory cell arrays, and a group including at least some of the plurality of memory cell arrays may be defined as a bank.

Each of memory cells configuring the memory cell array may include a cell transistor serving as a switch and a cell capacitor for storing data. To prevent data stored in the cell capacitor from being erased, a refresh operation for recharging the data in the memory cell is required. The refresh operation may be divided into an all-bank refresh operation that is performed on all banks, and a single bank refresh operation or a per-bank refresh operation that is performed on each bank.

In the all-bank refresh operation, a plurality of banks may be sequentially refreshed to reduce peak noise which may occur due to the simultaneous refresh operation of the plurality of banks. In this case, a sensing margin may be changed due to a difference in voltage conditions of each bank, and thus, data may not be accurately sensed during read and write operations, thereby causing an error.

### SUMMARY

Embodiments of the present disclosure are directed to a memory device capable of independently adjusting a sensing timing for each bank to thereby uniformly maintain a sensing margin during an all-bank refresh operation, and an operating method thereof.

According to an embodiment of the present disclosure, a memory device includes first to n-th banks, where n is a positive integer of 2 or more; a storage circuit configured to store first voltage information representing a voltage condition during an active operation and second voltage information representing a voltage condition during a refresh operation; and a sensing control circuit configured to select one of the first voltage information and the second voltage information according to a refresh section signal and a bank selection signal designating a k-th bank, where k is an integer equal to or less than n, among the first to n-th banks, and control a sensing timing for each of the first to n-th banks based on the selected voltage information.

According to an embodiment of the present disclosure, a memory device includes first to n-th banks, where n is a positive integer of 2 or more; a refresh control circuit configured to control at least two refresh operations each for refreshing all of the first to n-th banks and generate a first refresh section signal staying activated during each of the refresh operations and a second refresh section signal staying activated until all of the refresh operations are completed, according to a refresh command; and a sensing control circuit configured to select one of first voltage information and second voltage information according to the first and second refresh section signals and a bank selection signal designating a k-th bank, where k is an integer equal to or less than n, among the first to n-th banks and control a sensing timing for each of the first to n-th banks based on the selected voltage information.

According to an embodiment of the present disclosure, an operating method of a memory device including receiving a refresh command; activating a refresh section signal and sequentially activating first to n-th bank active signals, where n is a positive integer of 2 or more, according to the refresh command; and refreshing the first to n-th banks according to the first to n-th bank active signals, while selecting one of first voltage information and second voltage information according to the refresh section signal and a bank selection signal designating a k-th bank, where k is an integer equal to or less than n, among the first to n-th banks and controlling a sensing timing for each of the first to n-th banks based on the selected voltage information.

According to an embodiment of the present disclosure, an operating method of a memory device includes receiving a refresh command; performing at least two refresh operations each of refreshing all of first to n-th banks, where n is a positive integer of 2 or more, according to the refresh command; generating, according to the refresh command, a first refresh section signal staying activated during each of the refresh operations and a second refresh section signal staying activated until all of the refresh operations are completed; and selecting one of first voltage information and second voltage information according to the first and second refresh section signals and a bank selection signal designating a k-th bank, where k is an integer equal to or less than n, among the first to n-th banks and controlling a sensing timing for each of the first to n-th banks based on the selected voltage information.

Further, according to embodiments of the present disclosure, the memory device can improve the accuracy of sensing data by uniformly maintaining the sensing margin of each bank during the all-bank refresh operation. Accordingly, it is possible to improve the performance and reliability of the memory device.

### BRIEF DESCRIPTION OF THE DRAWINGS

FIG. 1 is a block diagram illustrating a memory device according to an embodiment of the present disclosure.

FIG. 2 is a detailed circuit diagram illustrating a configuration of a bank sense amplifier circuit of FIG. 1.

FIG. 3 is a detailed block diagram illustrating a timing control circuit of FIG. 1.

FIG. 4 is a detailed circuit diagram illustrating a selection control circuit of FIG. 3.

FIG. 5 is a circuit diagram illustrating a target bank selector according to another embodiment of the present disclosure.

FIG. 6 is a detailed circuit diagram illustrating a selection circuit of FIG. 3.

FIG. 7 is a timing diagram for describing an operation of the memory device of FIG. 1, according to an embodiment of the present disclosure.

FIG. 8 is a block diagram illustrating a memory device according to another embodiment of the present disclosure.

FIG. 9 is a detailed block diagram illustrating a timing control circuit of FIG. 8.

FIG. 10 is a detailed circuit diagram illustrating a selection control circuit of FIG. 9.

FIGS. 11A and 11B are timing diagrams for describing an operation of the memory device of FIG. 8, according to an embodiment of the present disclosure.

FIG. 12 is a block diagram illustrating a memory system according to an embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

Hereinafter, a memory device is described as a semiconductor device including a sampling circuit. However, the embodiments of the present disclosure are not limited thereto, and may be applied to all semiconductor devices including a sampling circuit for randomly sampling an input address or input signals.

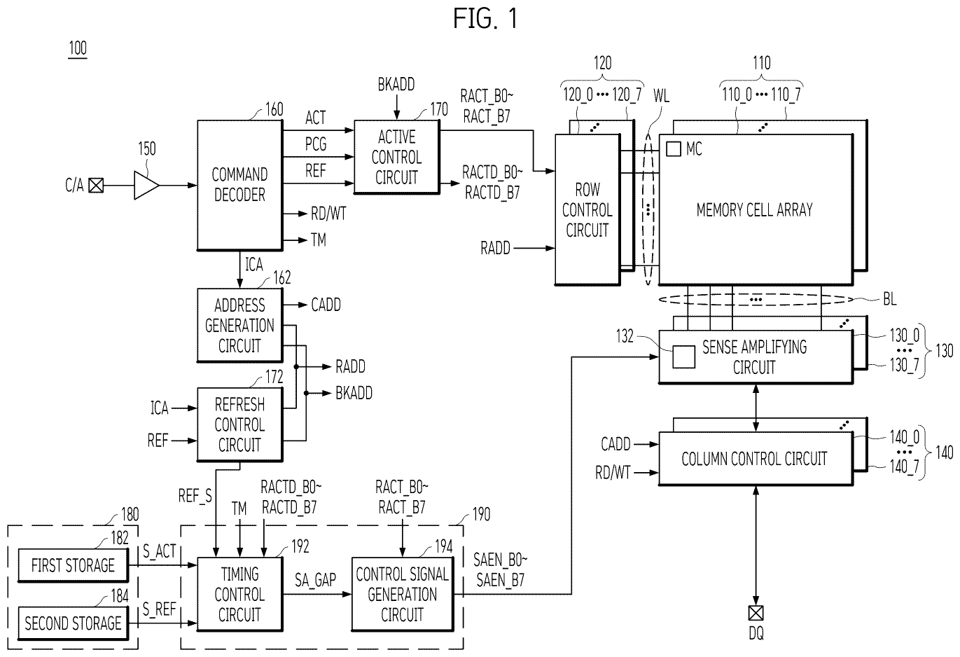

FIG. 1 is a block diagram illustrating a memory device 100 in accordance with an embodiment of the present disclosure.

Referring to FIG. 1, the memory device 100 may include a memory cell array 110, a row control circuit 120, a sense amplifying circuit 130, a column control circuit 140, a command/address (CA) receiving circuit 150, a command decoder 160, an address generation circuit 162, an active control circuit 170, a refresh control circuit 172, a storage circuit 180, and a sensing control circuit 190.

The memory cell array 110 may include a plurality of memory cells MC disposed in an array type. The plurality of memory cells MC may be respectively coupled to a plurality of word lines WL and a plurality of bit lines BL. The plurality of word lines WL may extend in a first direction (e.g., a row direction) and may be sequentially disposed in a second direction (e.g., a column direction) perpendicular to the first direction. The plurality of bit lines BL may extend in the column direction and may be sequentially disposed in the row direction.

The memory cell array 110 may be divided into a plurality of bank arrays. In the following embodiment, a case in which the memory cell array 110 is divided into first to eighth bank arrays 110_0 to 110_7 will be described as an example. The row control circuit 120 may include first to eighth bank row control circuits 120_0 to 120_7 coupled to the first to eighth bank arrays 110_0 to 110_7 through the plurality of word lines WL, respectively. The sense amplifier circuit 130 may include first to eighth bank sense amplifier circuits 130_0 to 130_7 coupled to the first to eighth bank arrays 110_0 to 110_7 through the plurality of bit lines BL, respectively. The column control circuit 140 may include first to eighth bank column control circuits 140_0 to 140_7 coupled to the first to eighth bank sense amplifier circuits 130_0 to 130_7, respectively. The first to eighth bank arrays 110_0 to 110_7, the first to eighth bank row control circuits 120_0 to 120_7, the first to eighth bank sense amplifier circuits 130_0 to 130_7, and the first to eighth bank column control circuits 140_0 to 140_7 may constitute first to eighth banks, respectively. The number of bank arrays or the number of memory cells MC may be determined according to the capacity of the memory device 100.

For reference, a bank address BKADD to be described later may be an address for selecting one of the first to eighth banks, a row address RADD may be an address for selecting one of the plurality of word lines WL, and a column address CADD may be an address for selecting some bit lines on which a read and write operation are to be performed among the plurality of bit lines BL. Each of the bank address BKADD, the row address RADD, and the column address CADD may be formed of multiple bits.

The first to eighth bank row control circuits 120_0 to 120_7 may receive first to eighth bank active signals RACT_B0 to RACT_B7, respectively. The first to eighth bank row control circuits 120_0 to 120_7 may each perform an active operation of activating a word line WL selected by the row address RADD according to a corresponding bank active signal, and may perform a precharge operation of precharging the activated word line WL.

The first to eighth bank sense amplifier circuits 130_0 to 130_7 may receive first to eighth sensing control signals SAEN_B0 to SAEN_B7, respectively. The first to eighth bank sense amplifier circuits 130_0 to 130_7 may sense and amplify a voltage difference between bit lines BL that is charge-shared by the activated word line WL, respectively, according to a corresponding sensing control signal. The first to eighth bank sense amplifier circuits 130_0 to 130_7 may include a plurality of bit line sense amplifiers 132 corresponding to the plurality of bit lines BL.

The first to eighth bank column control circuits 140_0 to 140_7 may select bit lines BL selected by the column address CADD. The first to eighth bank column control circuits 140_0 to 140_7 may read data DQ from the memory cells MC through the selected bit lines BL according to a read command RD, and write data DQ provided from the outside through a data pad to the memory cells MC through the selected bit lines BL according to a write command WT.

The CA receiving circuit 150 may receive a command/address signal C/A. Depending on a type of memory device 100, a command and an address may be input through the same input terminals, or a command and an address may be input through separate input terminals, where it is illustrated that a command and an address are input through the same input terminals. The command/address signal C/A may be composed of multiple bits.

The command decoder 160 may decode the command/address signal C/A received by the command/address receiving circuit 120 to generate an active command ACT, a precharge command PCG, the write command WT, the read command RD, and a refresh command REF. The active command ACT is a signal input when an active operation is indicated, the precharge command PCG is a signal input when a precharge operation is indicated, the write command WT is a signal input when a write operation is indicated, and the read command RD may be a signal input when a read operation is indicated. In addition, the refresh command REF may be a signal input when a refresh operation is indicated. In an embodiment of the present disclosure, a refresh operation may be divided into an all-bank refresh operation and a per-bank refresh operation, and the refresh command REF may include information on an all-bank refresh operation or a per-bank refresh operation. When an all-bank refresh operation is indicated, all of the first to eighth banks may be refreshed during a refresh cycle tRFC according to one refresh command REF. When the per-bank refresh operation is indicated, a bank designated by the bank address BKADD among the first to eighth banks may be refreshed according to one refresh command REF.

The command decoder 160 may decode the command/address signal C/A to further generate a test mode signal TM. The test mode signal TM may be composed of multiple bits. Depending on the embodiment, a mode register for storing various setting values may be disposed in the memory device 100, and the mode register may output a setting value corresponding to the internal address ICA received from the command decoder 160 as the test mode signal TM.

The address generation circuit 162 may classify the internal address ICA received from the command decoder 160 into the bank address BKADD, the row address RADD, and the column address CADD. For example, the address generation circuit 162 may classify the internal address ICA as the bank address BKADD and the row address RADD when an active operation is indicated as a result of the decoding of the command decoder 160, and classify the internal address ICA as the column address CADD when a read and write operation are indicated.

The active control circuit 170 may generate the first to eighth bank active signals RACT_B0 to RACT_B7 according to the active command ACT, the precharge command PCG, and the refresh command REF, while activating a bank active signal corresponding to the bank address BKADD among the first to eighth bank active signals RACT_B0 to RACT_B7. The active control circuit 170 may generate a bank active signal corresponding to the bank address BKADD, which is activated in response to the active command ACT and deactivated in response to the precharge command PCG. The active control circuit 170 may generate a bank active signal corresponding to the bank address BKADD, which is activated for a predetermined period (e.g., a row address strobe minimum time tRAS) in response to the refresh command REF. For example, when a refresh command REF indicating an all-bank refresh operation is input, the active control circuit 170 may sequentially activate the first to eighth bank active signals RACT_B0 to RACT_B7 according to the bank address BKADD during the refresh cycle tRFC. On the other hand, when a refresh command REF indicating a per-bank refresh operation is input, the active control circuit 170 may activate a bank active signal corresponding to the bank address BKADD during the refresh cycle tRFC. In addition, the active control circuit 170 may delay the first to eighth bank active signals RACT_B0 to RACT_B7 for a predetermined time and output the first to eighth delayed bank active signals RACTD_B0 to RACTD_B7, respectively.

The refresh control circuit 172 may generate the bank address BKADD and the row address RADD, to thereby designate a word line of a bank to be refreshed in response to the refresh command REF. For example, according to the refresh command REF indicating an all-bank refresh operation, the refresh control circuit 172 may sequentially increase one of the of the bank address BKADD and the row address RADD by “+1” so that the word lines WL of the first to eighth banks may be refreshed during the refresh cycle tRFC. For example, the refresh control circuit 172 may perform an operation of sequentially increasing the value of the row address RADD by “+1” until the value of the row address RADD reaches a maximum value, and when the value of the row address RADD reaches the maximum value, increasing the value of the bank address BKADD by “+1” while initializing the row address RADD. The refresh control circuit 172 may repeatedly perform the above operation until the value of the bank address BKADD reaches a maximum value. On the other hand, according to the refresh command REF indicating a per-bank refresh operation, the refresh control circuit 172 may generate the bank address BKADD corresponding to the internal address ICA, and may sequentially increase the value of the row address RADD by “+1” so that the word lines WL of the bank designated by the bank address BKADD among the first to eighth banks may be refreshed.

In addition, the refresh control circuit 172 may generate a refresh section signal REF_S in response to the refresh command REF. The refresh control circuit 172 may generate the refresh section signal REF_S activated for the all-bank refresh operation according to the refresh command REF indicating the all-bank refresh operation. According to an embodiment, the refresh control circuit 172 may additionally receive first to eighth bank active signals RACT_B0 to RACT_B7, and may generate the refresh section signal REF_S activated when any of the first to eighth bank active signals RACT_B0 to RACT_B7 is activated. In the following embodiment, a case in which the first to eighth bank active signals RACT_B0 to RACT_B7 are signals activated to a logic low level and the refresh section signal REF_S is a signal activated to a logic high level will be described as an example.

According to an embodiment, a plurality of multiplexers for selectively providing the bank address BKADD and the row address RADD output from the address generation circuit 162 and the bank address BKADD and the row address RADD output from the refresh control circuit 172 to the active control circuit 170 may be further provided. When the refresh command REF is input, the multiplexers may provide the bank address BKADD and the row address RADD output from the refresh control circuit 172 to the active control circuit 170.

The storage circuit 180 may store first voltage information S_ACT representing a voltage condition during an active operation, and store second voltage information S_REF representing a voltage condition during a refresh operation. The storage circuit 180 may detect an optimal voltage condition during an active operation of the memory device 100, and detect an optimal voltage condition during a refresh operation of the memory device 100, through a test operation during manufacturing. The optimal voltage condition may include delay values for controlling a sensing timing. The storage circuit 180 may store the detected optimal voltage conditions as first voltage information S_ACT and second voltage information S_REF, respectively. The storage circuit 180 may include a first storage device 182 for storing first voltage information S_ACT and a second storage device 184 for storing second voltage information S_REF. The first voltage information S_ACT and the second voltage information S_REF may each consist of multiple bits, and a case of a signal consisting of 4-bit will be described as an example in the following embodiment.

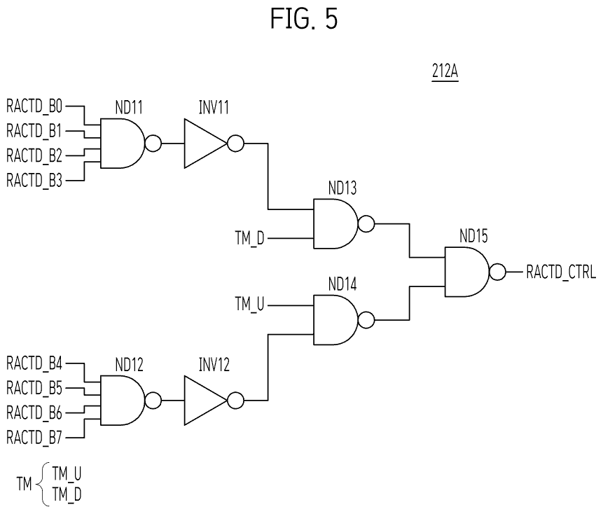

The sensing control circuit 190 may receive, as a bank selection signal (RACTD_CTRL of FIG. 4), a delayed bank active signal selected according to the test mode signal TM from among the first to eighth delayed bank active signals RACTD_B0 to RACTD_B7. The sensing control circuit 190 may select one of the first voltage information S_ACT stored in the first storage 182 and the second voltage information S_REF stored in the second storage 184, according to the refresh section signal REF_S and the bank selection signal RACTD_CTRL, and independently control sensing timings for the first to eighth banks based on the selected voltage information. For example, when a third delayed bank active signal RACTD_B2 is selected as the bank selection signal RACTD_CTRL according to the test mode signal TM, the sensing control circuit 190 may adjust the sensing timings for the first to third banks based on the second voltage information S_REF, and adjust the sensing timings for the fourth to eighth banks based on the first voltage information S_ACT, when the refresh section signal REF_S is activated.

In more detail, the sensing control circuit 190 may include a timing control circuit 192 and a control signal generation circuit 194.

The timing control circuit 192 may receive, as the bank selection signal RACTD_CTRL, a delayed bank active signal selected according to the test mode signal TM from among of the first to eighth delayed bank active signals RACTD_B0 to RACTD_B7, and output, as target voltage information SA_GAP, voltage information selected according to the refresh section signal REF_S and the bank selection signal RACTD_CTRL from among the first voltage information S_ACT and the second voltage information S_REF.

The control signal generation circuit 194 may generate the first to eighth sensing control signals SAEN_B0 to SAEN_B7 corresponding to the first to eighth bank active signals RACT_B0 to RACT_B7, while adjusting an activation timing of each of the first to eighth sensing control signals SAEN_B0 to SAEN_B7 according to the target voltage information SA_GAP. Since the activation timing of each of the first to eighth sensing control signals SAEN_B0 to SAEN_B7 is adjusted, the sensing timing of each of the first to eighth bank sense amplifier circuits 130_0 to 130_7 may be adjusted.

Hereinafter, it will be described that the sensing timing of each of the first to eighth bank sense amplifier circuits 130_0 to 130_7 is adjusted by each of the first to eighth sensing control signals SAEN_B0 to SAEN_B7.

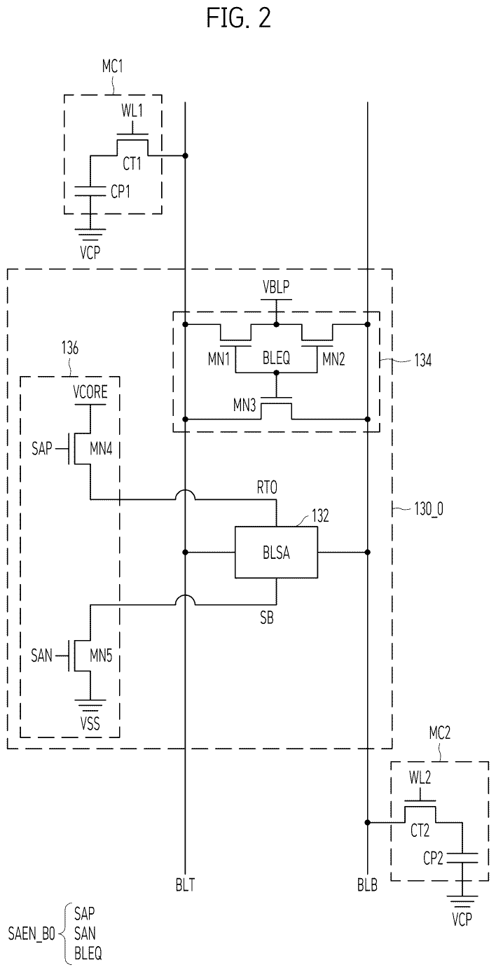

FIG. 2 is a detailed circuit diagram illustrating a configuration of a bank sense amplifier circuit of FIG. 1.

Referring to FIG. 2, a first bank sense amplifier circuit 130_0 for sensing and amplifying a voltage difference of a first bit line BLT and a second bit line BLB coupled to the first and second memory cells MC1 and MC2, respectively, is illustrated.

The first memory cell MC1 may be coupled between a first word line WL1 and the first bit line BLT, and include a cell transistor CT1 and a cell capacitor CP1. The cell capacitor CP1 may be coupled between a cell plate voltage (VCP) terminal and the cell transistor CT1, and the cell transistor CT1 may be coupled between the cell capacitor CP1 and the first bit line BLT, and have a gate receiving a signal at the first word line WL1. Likewise, the second memory cell MC2 may be coupled between a second word line WL2 and the second bit line BLB, and include a cell transistor CT2 and a cell capacitor CP2. The cell capacitor CP2 may be coupled between the cell plate voltage (VCP) terminal and the cell transistor CT2, and the cell transistor CT2 may be coupled between the cell capacitor CP2 and the second bit line BLB, and have a gate receiving a signal at the second word line WL2. For reference, when the first word line WL1 is activated, the first bit line BLT coupled to the cell transistor CT1 to be turned on becomes a target bit line from which an output data is outputted, and the second bit line BLB becomes a reference bit line. Moreover, when the second word line WL2 is activated, the second bit line BLB coupled to the cell transistor CT2 to be turned on becomes a target bit line from which an output data is outputted, and the first bit line BLT becomes a reference bit line.

The first bank sense amplifier circuit 130_0 may include a bit line sense amplifier (BLSA) 132, a precharge circuit 134, and a voltage driving circuit 136.

The BLSA 132 may be coupled between a pull-up voltage line RTO and a pull-down voltage line SB, and sense a change in a voltage between the first bit line BLT and the second bit line BLB.

The precharge circuit 134 may supply a precharge voltage VBLP to the first bit line BLT and the second bit line BLB, in response to an equalizing signal BLEQ. The precharge voltage VBLP may have an intermediate voltage level between a ground voltage VSS and a core voltage VCORE. The core voltage VCORE may have a voltage level lower than a supply voltage VDD. The precharge circuit 134 may include first to third NMOS transistors MN1 to MN3.

The voltage driving circuit 136 may drive the pull-up voltage line RTO and the pull-down voltage line SB by supplying operating voltages to the pull-up voltage line RTO and the pull-down voltage line SB. The voltage driving circuit 136 may include a pull-up driver MN4 and a pull-down driver MN5. The pull-up driver MN4 may provide the core voltage VCORE to the pull-up voltage line RTO in response to a pull-up control signal SAP. The pull-down driver MN5 may provide the ground voltage VSS to the pull-down voltage line SB in response to a pull-down control signal SAN. Each of the pull-up driver MN4 and the pull-down driver MN5 may be implemented with an NMOS transistor.

The operation of the first bank sense amplifier circuit 130_0 with the above configuration is as follows. First, when the equalizing signal BLEQ is activated during a precharge operation, the first bit line BLT and the second bit line BLB coupled to the first memory cell MC1 and the second memory cell MC2 are precharged to the precharge voltage VBLP. After the precharge operation, for example, when the first word line WL1 is activated, the cell transistor CT1 in the first memory cell MC1 may be turned on, resulting in a charge sharing operation in which the charge of the cell capacitor CP1 in the first memory cell MC1 flows into the first bit line BLT. By the charge sharing operation, the voltage at the first bit line BLT may be decreased or increased by the amount of voltage change from the precharge voltage VBLP. After the charge sharing operation, a pull-up voltage (i.e., the core voltage VCORE) is supplied to the pull-up voltage line RTO, and a pull-down voltage (i.e., the ground voltage VSS) is supplied to the pull-down voltage line SB. The BLSA 132 may perform an amplifying operation by sensing and amplifying a voltage difference between the first bit line BLT and the second bit line BLB.

Moreover, each of the first to eighth sensing control signals SAEN_B0 to SAEN_B7 may include the equalization signal BLEQ, the pull-up control signal SAP, and the pull-down control signal SAN of FIG. 2. In an embodiment of the present disclosure, the control signal generation circuit 194 may adjust the activation timing of the pull-up control signal SAP and/or the pull-down control signal SAN provided to each bank sense amplifier circuit according to the target voltage information SA_GAP. That is, the first bank sense amplifier circuit 130_0 may adjust the sensing timing of the bit line sense amplifier 132 by controlling a timing of supplying the pull-up voltage and the pull-down voltage according to the pull-up control signal SAP and the pull-down control signal SAN.

Hereinafter, a detailed configuration of the timing control circuit 192 of FIG. 1 will be described.

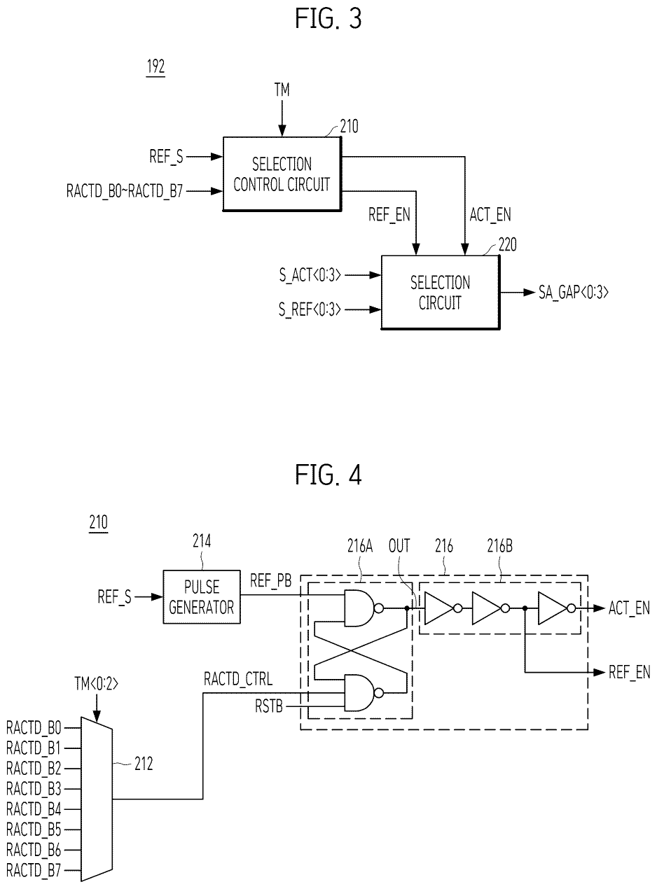

FIG. 3 is a detailed block diagram illustrating the timing control circuit 192 of FIG. 1.

Referring to FIG. 3, the timing control circuit 192 may include a selection control circuit 210 and a selection circuit 220.

The selection control circuit 210 may receive, as the bank selection signal RACTD_CTRL, a delayed bank active signal selected according to the test mode signal TM from among the first to eighth delayed bank active signals RACTD_B0 to RACTD_B7. The selection control circuit 210 may activate a first selection signal ACT_EN or a second selection signal REF_EN according to the refresh section signal REF_S and the bank selection signal RACTD_CTRL. The first selection signal ACT_EN and the second selection signal REF_EN may be complementary signals having opposite logic levels. For example, the selection control circuit 210 may activate the second selection signal REF_EN and deactivate the first selection signal ACT_EN when the refresh section signal REF_S is activated. The selection control circuit 210 may deactivate the second selection signal REF_EN and activate the first selection signal ACT_EN when the bank selection signal RACTD_CTRL is activated. In the following embodiment, a case in which the first selection signal ACT_EN and the second selection signal REF_EN are signals activated to a logic high level will be described as an example.

The selection circuit 220 may select one of the first voltage information S_ACT<0:3> and the second voltage information S_REF<0:3> according to the first selection signal ACT_EN and the second selection signal REF_EN, and output the selected signal as the target voltage information SA_GAP<0:3>. The selection circuit 220 may output, as the target voltage information SA_GAP<0:3>, the first voltage information S_ACT<0:3> selected according to the first selection signal ACT_EN, or the second voltage information S_REF<0:3> selected according to the second selection signal REF_EN.

FIG. 4 is a detailed circuit diagram illustrating the selection control circuit 210 of FIG. 3.

Referring to FIG. 4, the selection control circuit 210 may include a target bank selector 212, a pulse generator 214, and a latch output circuit 216. In the embodiment of FIG. 4, a case in which the test mode signal TM<0:2> is configured to have 3-bit to select one of the first to eighth banks is illustrated.

The target bank selector 212 may output, as the bank selection signal RACTD_CTRL, a delayed bank active signal selected according to the test mode signal TM<0:2> of 3-bit from among the first to eighth delayed bank active signals RACTD_B0 to RACTD_B7. For example, the target bank selector 212 may select the first delayed bank active signal RACTD_B0 as the bank selection signal RACTD_CTRL according to the test mode signal TM<0:2> of “000”, select the second delayed bank active signal RACTD_B1 as the bank selection signal RACTD_CTRL according to the test mode signal TM<0:2> of “001”, and in this way, select the eighth delayed bank active signal RACTD_B7 as the bank selection signal RACTD_CTRL according to the test mode signal TM<0:2> of “111”. The target bank selector 212 may be implemented with a known multiplexer.

The pulse generator 214 may generate a set signal REF_PB that is pulsing when the refresh section signal REF_S is activated. For example, the pulse generator 214 may generate the set signal REF_PB that is pulsing to a logic low level for a predetermined period, when the refresh section signal REF_S is activated to a logic high level, i.e., according to a rising edge of the refresh section signal REF_S.

The latch output circuit 216 may generate the second selection signal REF_EN which is activated according to the set signal REF_PB and deactivated according to the bank selection signal RACTD_CTRL, and may generate the first selection signal ACT_EN by inverting the second selection signal REF_EN. The latch output circuit 216 may activate the first selection signal ACT_EN and deactivate the second selection signal REF_EN, in response to a global reset signal RSTB which is activated to a logic low level during initialization.

In more detail, the latch output circuit 216 may include an SR latch 216A and a buffer 216B. The SR latch 216A may be implemented with cross-coupled NAND gates. The SR latch 216A may generate an output signal OUT which is activated according to a falling edge of the set signal REF_PB, and is deactivated according to a falling edge of the bank selection signal RACTD_CTRL or the global reset signal RSTB. The buffer 216B may be implemented with a predetermined number of inverters. The buffer 216B may output the second selection signal REF_EN by buffering the output signal OUT, and output the first selection signal ACT_EN by inverting the second selection signal REF_EN.

In FIG. 4, a case where the test mode signal TM<0:2> is configured with 3-bit to select one of the first to eighth banks has been described as an example, but the embodiments are is not limited thereto. According to an embodiment, the test mode signal TM may include an upper test mode signal TM_U and a lower test mode signal TM_D configured with 1-bit, respectively. The upper test mode signal TM_U and the lower test mode signal TM_D may be complementary signals having opposite logic levels.

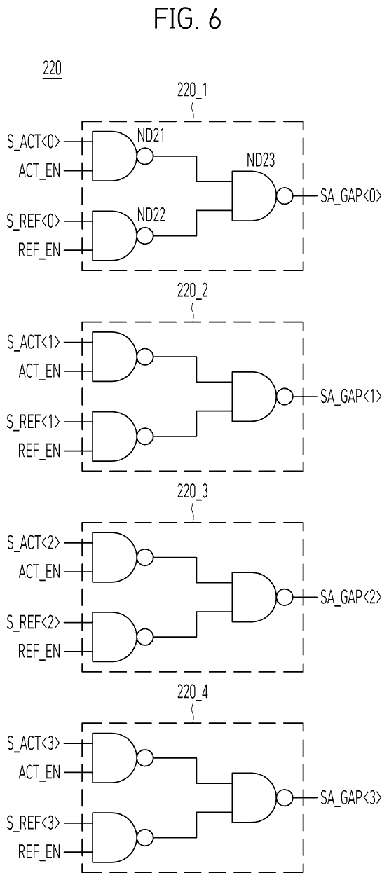

FIG. 5 is a circuit diagram illustrating a target bank selector 212A according to another embodiment of the present disclosure.

Referring to FIG. 5, the target bank selector 212A may include first and second inverters INV11 and INV12 and first to fifth NAND gates ND11 to ND15.

The first NAND gate ND11 and the first inverter INV11 may perform a logic AND operation on the first to fourth delayed bank active signals RACTD_B0 to RACTD_B3 corresponding to lower banks, and the second NAND gate ND12 and the second inverter INV12 may perform a logic AND operation on the fifth to eighth delayed bank active signals RACTD_B4 to RACTD_B7 corresponding to upper banks. The third NAND gate ND13 may perform a logic NAND operation on an output signal of the first inverter INV11 and a lower test mode signal TM_D, and the fourth NAND gate ND14 may perform a logic NAND operation on an output signal of the second inverter INV12 and an upper test mode signal TM_U, and the fifth NAND gate ND15 may perform a logic NAND operation on an output signal of the third NAND gate ND13 and an output signal of the fourth NAND gate ND14 to output the bank selection signal RACTD_CTRL.

With the above configuration, the target bank selector 212A may output, as the bank selection signal RACTD_CTRL, a delayed bank active signal selected according to the lower test mode signal TM_D from among the first to fourth delayed bank active signals RACTD_B0 to RACTD_B3 corresponding to the lower banks, or a delayed bank active signal selected according to the upper test mode signal TM_U from among the fifth to eighth delayed bank active signals RACTD_B4 to RACTD_B7 corresponding to the upper banks.

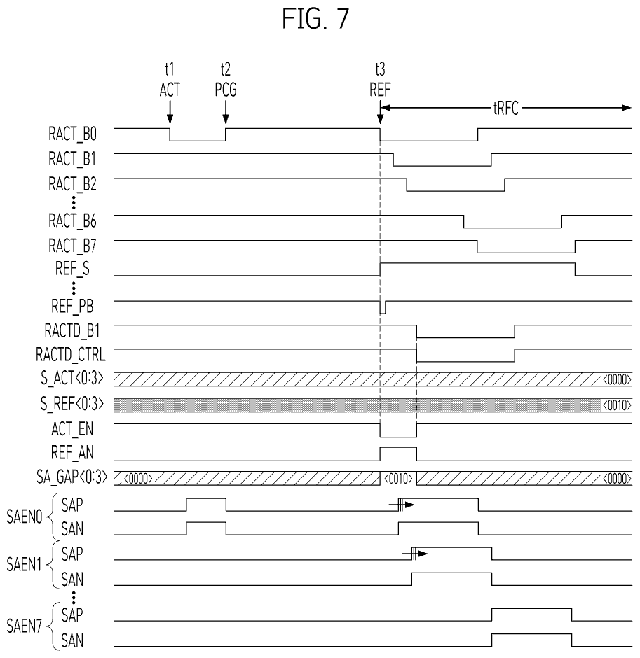

FIG. 6 is a detailed circuit diagram illustrating the selection circuit 220 of FIG. 3.

Referring to FIG. 6, the selection circuit 220 may include first to fourth bit selectors 220_1 to 220_4 corresponding to each bit in the target voltage information SA_GAP<0:3>. Since the first to fourth bit selectors 220_1 to 220_4 have the same configuration, the first bit selector 220_1 will be described as an example.

The first bit selector 220_1 may include first to third NAND gates ND21 to ND23.

The first NAND gate ND21 may perform a logic NAND operation on a first bit S_ACT<0:3> of the first voltage information S_ACT<0:3> and the first selection signal ACT_EN. The second NAND gate ND22 may perform a logic NAND operation on a first bit S_REF<0:3> of the second voltage information S_REF<0:3> and the second selection signal REF_EN. The third NAND gate ND23 may perform a logic NAND operation on an output signal of the first NAND gate ND21 and an output signal of the second NAND gate ND22 to output a first bit SA_GAP<0> of the target voltage information SA_GAP<0:3>.

With the above configuration, the selection circuit 220 may output, as the target voltage information SA_GAP<0:3>, the first voltage information S_ACT<0:3> selected according to the first selection signal ACT_EN, or the second voltage information S_REF<0:3> selected according to the second selection signal REF_EN.

Hereinafter, an operation of the memory device 100 according to an embodiment of the present disclosure will be described with reference to FIGS. 1 to 7.

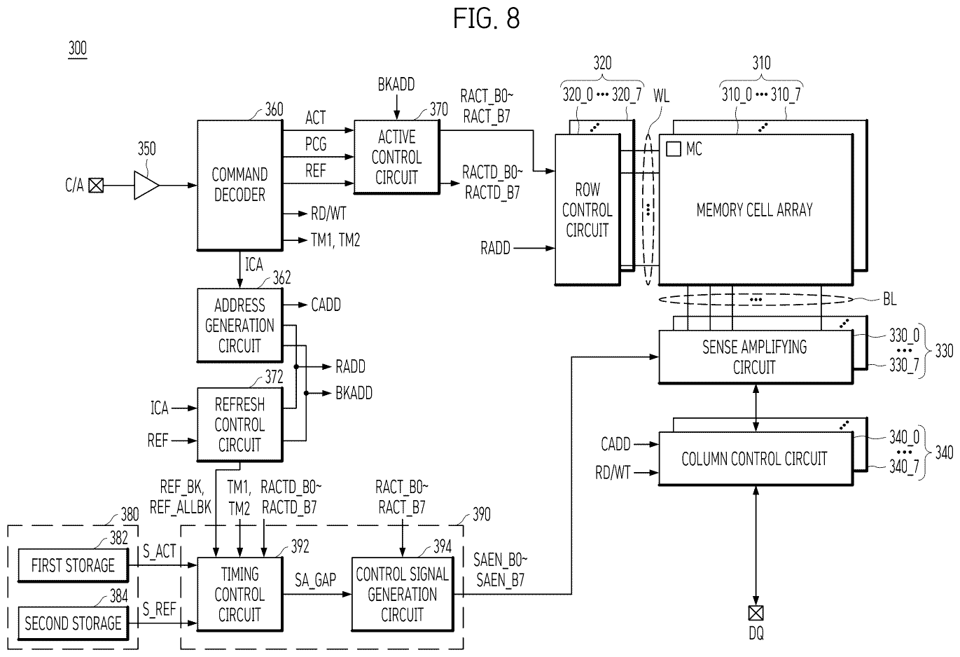

FIG. 7 is a timing diagram for describing an operation of the memory device 100 of FIG. 1, according to an embodiment of the present disclosure.

Referring to FIG. 7, through a test operation, first voltage information S_ACT<0:3> of “0000” is set and stored, and second voltage information S_REF<0:3> of “0010” is set and stored. During initialization, according to a global reset signal RSTB, a first selection signal ACT_EN may be activated to a logic high level, and a second selection signal REF_EN may be deactivated to a logic low level.

At a time point t1, an active command ACT and a bank address BKADD for designating a bank (e.g., a first bank) to be activated may be input from an external device (e.g., a memory controller). The active control circuit 170 may activate a first bank active signal RACT_B0 corresponding to the bank address BKADD to a logic low level according to the active command ACT. The control signal generation circuit 194 may activate a pull-up control signal SAP and a pull-down control signal SAN to a logic high level depending on the first voltage information S_ACT set to “0000” according to the activated first selection signal ACT_EN. Accordingly, the first bank sense amplifier circuit 130_0 may sense and amplify a voltage difference between the bit lines BLT and BLB.

At a time point t2, when a precharge command PCG is input from the memory controller, the active control circuit 170 may deactivate the first bank active signal RACT_B0 to a logic high level, and the control signal generation circuit 194 may deactivate the pull-up control signal SAP and the pull-down control signal SAN to a logic low level. Although not shown, the control signal generation circuit 194 may activate the equalization signal BLEQ to precharge the bit lines BLT and BLB.

At a time point t3, a refresh command REF indicating an all-bank refresh operation may be input from the memory controller. In this case, the test mode signal TM for selecting the second bank is set.

The refresh control circuit 172 may increase a value of the bank address BKADD by “+1” so that the first to eighth banks may be selected during a refresh cycle tRFC, and accordingly, the active control circuit 170 may sequentially activate the first to eighth bank active signals RACT_B0 to RACT_B7. The refresh control circuit 172 may generate a refresh section signal REF_S that is activated during an all-bank refresh operation.

The selection control circuit 210 may receive a second delayed bank active signal RACTD_B1 as the bank selection signal RACTD_CTRL according to the test mode signal TM and generate a set signal REF_PB that is pulsing to a logic low level for a predetermined period according to a rising edge of the refresh section signal REF_S. The selection control circuit 210 may activate the second selection signal REF_EN and deactivate the first selection signal ACT_EN according to a falling edge of the set signal REF_PB. Also, the selection control circuit 210 may deactivate the second selection signal REF_EN and activate the first selection signal ACT_EN according to a falling edge of the bank selection signal RACTD_CTRL. That is, the second selection signal REF_EN in which an activation section is defined by the set signal REF_PB and the bank selection signal RACTD_CTRL may be generated. The selection circuit 220 may output target voltage information SA_GAP<0:3> of “0000” corresponding to the first voltage information S_ACT<0:3> during an activation section of the first selection signal ACT_EN, and output the target voltage information SA_GAP<0:3> of “0010” corresponding to the second voltage information S_REF<0:3> during the activation section of the second selection signal REF_EN.

The control signal generation circuit 194 may output first to eighth sensing control signals SAEN_B0 to SAEN_B7 to the first to eighth bank sense amplifier circuits 130_0 to 130_7, respectively, by adjusting activation timings of the first to eighth sensing control signals SAEN_B0 to SAEN_B7 according to the target voltage information SA_GAP<0:3>. For example, for the first and second banks, the control signal generation circuit 194 may delay the activation timing of the pull-up control signal SAP of each of the first and second sensing control signals SAEN_B0 and SAEN_B1 to a first delay value according to the target voltage information SA_GAP<0:3> of “0010”. Furthermore, for the third to eighth banks, the control signal generation circuit 194 may delay the activation timing of the pull-up control signal SAP of each of the third to eighth sensing control signals SAEN_B2 to SAEN_B7 to a second delay value different from the first delay value, according to the target voltage information SA_GAP<0:3> of “0000”. Depending on an embodiment, the control signal generation circuit 194 may delay the activation timing of the pull-down control signal SAN other than the pull-up control signal SAP.

Accordingly, the first and second bank sense amplifier circuits 130_0, 130_1 may sense and amplify the voltage difference between the bit lines BLT and BLB at a sensing timing that is different from the third to eighth bank sense amplifier circuits 130_2 to 130_7.

As described above, in an embodiment of the present disclosure, when the sensing margins of the banks are changed during the all-bank refresh operation, since an initial voltage condition and a subsequent voltage condition after a predetermined time from initialization are changed, the sensing timings for the banks performing the refresh operation under the initial voltage condition and the sensing timings for the banks performing the refresh operation under the subsequent voltage condition may be independently adjusted. Accordingly, the accuracy of sensing data may be improved by uniformly maintaining the sensing margins of the banks during the all-bank refresh operation. Accordingly, it is possible to improve the performance and reliability of the memory device.

In the above embodiment, a case in which a refresh operation is performed once on a bank during a refresh cycle tRFC in response to one refresh command has been described, but the embodiments are not limited thereto. According to an embodiment, two or more refresh operations may be performed on a bank in response to one refresh command.

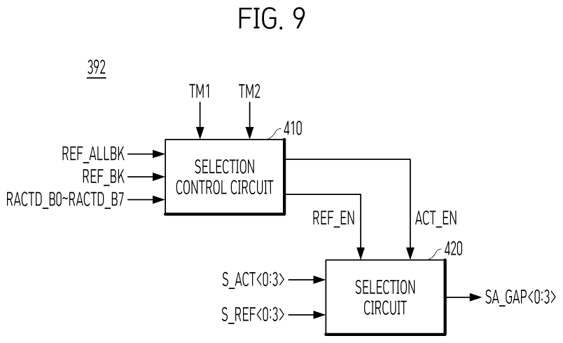

FIG. 8 is a block diagram illustrating a memory device 300 according to another embodiment of the present disclosure.

Referring to FIG. 8, the memory device 300 may include a memory cell array 310, a row control circuit 320, a sense amplifier circuit 330, a column control circuit 340, a command/address (CA) receiving circuit 350, a command decoder 360, an address generation circuit 362, an active control circuit 372, a refresh control circuit 372, a storage circuit 380, and a sensing control circuit 390.

The memory cell array 310, the row control circuit 320, the sense amplifier circuit 330, the column control circuit 340, the command/address receiving circuit 350, the address generation circuit 362, the active control circuit 370, and the storage circuit 380 of FIG. 8 may have substantially the same configuration and operation as those of FIG. 2.

That is, the cell array 310 of FIG. 8 may be divided into first to eighth bank arrays 310_0 to 310_7. The row control circuit 320 may include first to eighth bank row control circuits 320_0 to 320_7 coupled to the first to eighth bank arrays 310_0 to 310_7 through a plurality of word lines WL, respectively. The sense amplifier circuit 330 may include first to eighth bank sense amplifier circuits 330_0 to 330_7 coupled to the first to eighth bank arrays 310_0 to 310_7 through a plurality of bit lines BL, respectively. The column control circuit 340 may include first to eighth bank column control circuits 340_0 to 340_7 coupled to the first to eighth bank sense amplifier circuits 330_0 to 330_7, respectively. The first to eighth bank arrays 310_0 to 310_7, the first to eighth bank row control circuits 320_0 to 320_7, the first to eighth bank sense amplifier circuits 330_0 to 330_7, and the first to eighth bank column control circuits 340_0 to 340_7 may constitute first to eighth banks, respectively.

The command decoder 360 may decode a command/address signal C/A received by the command/address receiving circuit 320 to generate an active command ACT, a precharge command PCG, a write command WT, a read command RD, and a refresh command REF. Furthermore, the command decoder 360 may decode the command/address signal C/A to generate first and second test mode signals TM1 and TM2. At least one of the first and second test mode signals TM1 and TM2 may be composed of multiple bits. According to an embodiment, a mode register for storing various setting values may be disposed in the memory device 300, and the mode register may output setting values corresponding to an internal address ICA received from the command decoder 360 as the first and second test mode signals TM1 and TM2.

The refresh control circuit 372 may preset the number of refresh operations each to be performed on the first to eighth banks. The refresh control circuit 372 may control a preset number of refresh operations each for refreshing all of the first to eighth banks, during the refresh cycle tRFC, according to the refresh command REF indicating an all-bank refresh operation. The refresh control circuit 372 may increase and sequentially output values of a bank address BKADD and a row address RADD so that the word lines WL of the first to eighth banks may be refreshed the preset number of times. The refresh control circuit 372 may control, according to the refresh command REF indicating a per-bank refresh operation, the preset number of refresh operations each for refreshing a bank designated by the bank address BKADD corresponding to the internal address ICA. The refresh control circuit 372 may generate the bank address BKADD corresponding to the internal address ICA, and sequentially output the values of the row address RADD so that the word lines WL of the bank designated by the bank address BKADD among the first to eighth banks may be refreshed the preset number of times.

In addition, the refresh control circuit 372 may generate a first refresh section signal REF_BK and a second refresh section signal REF_ALLBK according to the refresh command REF. The refresh control circuit 372 may generate, according to the refresh command REF indicating an all-bank refresh operation, the first refresh section signal REF_BK, which stays activated each time a refresh operation is performed for all banks, and the second refresh section signal REF_ALLBK, which stays activated while the preset number of refresh operations are performed for all banks. According to an embodiment of the present disclosure, the first refresh section signal REF_BK may stay activated during each of the preset number of refresh operations. According to an embodiment of the present disclosure, the second refresh section signal REF_ALLBK may stay activated until all of the preset number of refresh operations are completed.

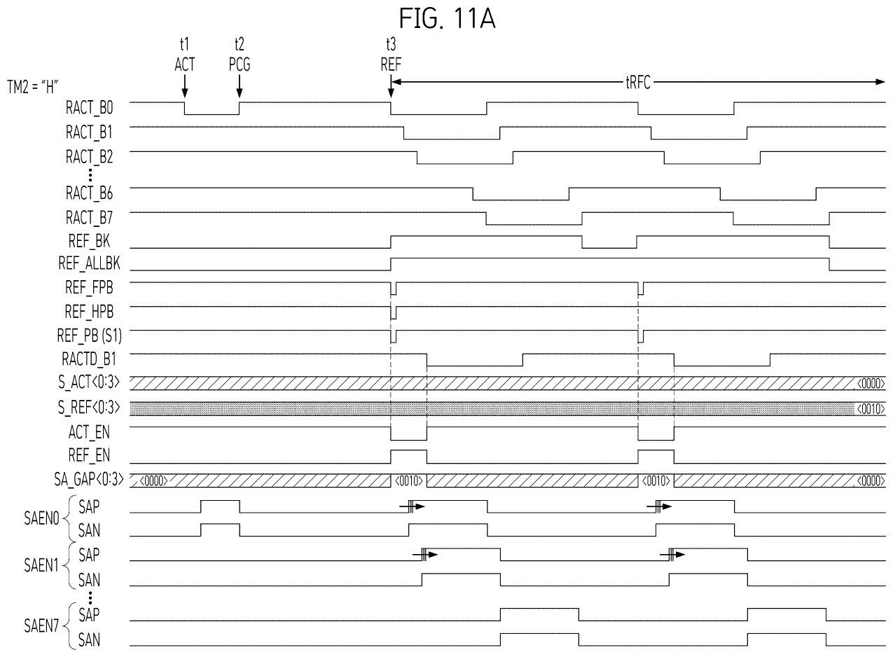

The sensing control circuit 390 may receive, as a bank selection signal (RACTD_CTRL of FIG. 10), a delayed bank active signal selected according to the first test mode signal TM1 from among the first to eighth delayed bank active signals RACTD_B0 to RACTD_B7. The sensing control circuit 390 may independently control sensing timings for the first to eighth banks based on a selected one from first voltage information S_ACT stored in a first storage 382 and second voltage information S_REF stored in a second storage 384, according to the second test mode signal TM2, the first refresh section signal REF_BK, the second refresh section signal REF_ALLBK, and the bank selection signal RACTD_CTRL. When the third delayed bank active signal RACTD_B2 is selected according to the first test mode signal TM1, the sensing control circuit 390 may adjust the sensing timings for the first to third banks based on the second voltage information S_REF, and adjust the sensing timings for the fourth to eighth banks based on the first voltage information S_ACT when a selected one of the first refresh section signal REF_BK and the second refresh section signal REF_ALLBK according to the second test mode signal TM2 is activated.

In more detail, the sensing control circuit 390 may include a timing control circuit 392 and a control signal generation circuit 394.

The timing control circuit 392 may receive, as the bank selection signal RACTD_CTRL, a delayed bank active signal selected according to the first test mode signal TM1 from among the first to eighth delayed bank active signals RACTD_B0 to RACTD_B7. The timing control circuit 392 may select one of the first refresh section signal REF_BK and the second refresh section signal REF_ALLBK according to the second test mode signal TM2, and output, as target voltage information SA_GAP, voltage information selected according to the bank selection signal RACTD_CTRL and the selected refresh section signal from among the first voltage information S_ACT and the second voltage information S_REF.

For example, when the second test mode signal TM2 is at a first logic level (e.g., a logic high level), the timing control circuit 392 may output, as the target voltage information SA_GAP, voltage information selected according to the first refresh section signal REF_BK and the bank selection signal RACTD_CTRL from among the first voltage information S_ACT and the second voltage information S_REF. On the other hand, when the second test mode signal TM2 is at a second logic level (e.g., a logic low level), the timing control circuit 392 may output, as the target voltage information SA_GAP, voltage information selected according to the second refresh section signal REF_ALLBK and the bank selection signal RACTD_CTRL from among the first voltage information S_ACT and the second voltage information S_REF.

The control signal generation circuit 394 may generate the first to eighth sensing control signals SAEN_B0 to SAEN_B7 corresponding to the first to eighth bank active signals RACT_B0 to RACT_B7, while adjusting an activation timing of each of the first to eighth sensing control signals SAEN_B0 to SAEN_B7 according to the target voltage information SA_GAP. Since the activation timing of each of the first to eighth sensing control signals SAEN_B0 to SAEN_B7 is adjusted, the sensing timing of each of the first to eighth bank sense amplifier circuits 330_0 to 330_7 may be adjusted.

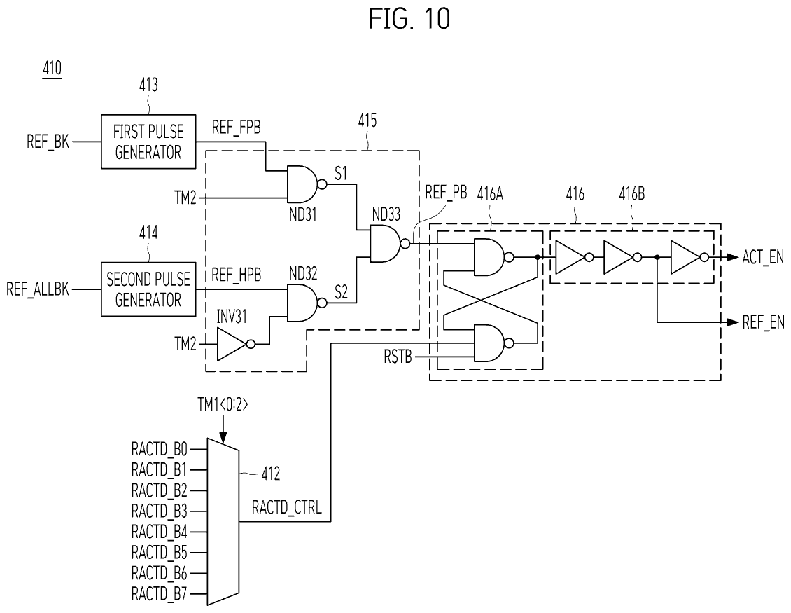

FIG. 9 is a detailed block diagram illustrating the timing control circuit 392 of FIG. 8.

Referring to FIG. 9, the timing control circuit 392 may include a selection control circuit 410 and a selection circuit 420.

The selection control circuit 410 may receive, as the bank selection signal RACTD_CTRL, a delayed bank active signal selected according to the first test mode signal TM1 from among the first to eighth delayed bank active signals RACTD_B0 to RACTD_B7. The selection control circuit 410 may select one of the first refresh section signal REF_BK and the second refresh section signal REF_ALLBK according to the second test mode signal TM2, and may activate the first selection signal ACT_EN or the second selection signal REF_EN according to the bank selection signal RACTD_CTRL and the selected refresh section signal.

The selection circuit 420 may output, as the target voltage information SA_GAP<0:3>, voltage information selected according to the first selection signal ACT_EN and the second selection signal REF_EN from among the first voltage information S_ACT<0:3> and the second voltage information S_REF<0:3>. The selection circuit 420 may output, as the target voltage information SA_GAP<0:3>, the first voltage information S_ACT<0:3> selected according to the first selection signal ACT_EN, or the second voltage information S_REF<0:3> selected according to the second selection signal REF_EN. The selection circuit 420 may have substantially the same configuration as the selection circuit 220 of FIG. 6.

FIG. 10 is a detailed circuit diagram illustrating the selection control circuit 410 of FIG. 9.

Referring to FIG. 10, the selection control circuit 410 may include a target bank selector 412, a first pulse generator 413, a second pulse generator 414, a pulse selector 415, and a latch output circuit 416. In the embodiment of FIG. 10, a case in which the first test mode signal TM 1<0:2> is configured to have 3-bit to select one of the first to eighth banks is illustrated.

The target bank selector 412 may output, as the bank selection signal RACTD_CTRL, a delayed bank active signal selected according to the first test mode signal TM 1<0:2> of 3-bit from among the first to eighth delayed bank active signals RACTD_B0 to RACTD_B7. The target bank selector 412 may have substantially the same configuration as the target bank selector 212 or 212A of FIG. 4 or 5.

The first pulse generator 413 may generate a first pulse signal REF_FPB that is pulsing when the first refresh section signal REF_BK is activated. For example, the first pulse generator 413 may generate the first pulse signal REF_FPB that is pulsing to a logic low level for a predetermined period, when the first refresh section signal REF_BK is activated to a logic high level, that is, according to a rising edge of the first refresh section signal REF_BK.

The second pulse generator 414 may generate a second pulse signal REF_HPB that is pulsing when the second refresh section signal REF_ALLBK is activated. For example, the second pulse generator 414 may generate the second pulse signal REF_HPB that is pulsing to a logic low level for a predetermined period, when the second refresh section signal REF_ALLBK is activated to a logic high level, that is, according to a rising edge of the second refresh section signal REF_ALLBK.

The pulse selector 415 may output, as a set signal REF_PB, one of the first pulse signal REF_FPB and the second pulse signal REF_HPB according to the second test mode signal TM2. For example, the pulse selector 415 may include a first inverter INV31 and first to third NAND gates ND31 to ND33. The first inverter INV31 may invert the second test mode signal TM2. The first NAND gate ND31 may perform a logic NAND operation on the first pulse signal REF_FPB and the second test mode signal TM2. The second NAND gate ND32 may perform a logic NAND operation on the second pulse signal REF_HPB and an output signal of the first inverter INV31. The third NAND gate ND33 may perform a logic NAND operation on an output signal of the first NAND gate ND31 and an output signal of the second NAND gate ND32, to output the set signal REF_PB. With this configuration, the pulse selector 415 may output, as the set signal REF_PB, the first pulse signal REF_FPB when the second test mode signal TM2 is at the first logic level (e.g., a logic high level), and the second pulse signal REF_HPB when the second test mode signal TM2 is at the second logic level (e.g., a logic low level).

The latch output circuit 416 may generate the second selection signal REF_EN which is activated according to the set signal REF_PB and deactivated according to the bank selection signal RACTD_CTRL, and may generate the first selection signal ACT_EN by inverting the second selection signal REF_EN. The latch output circuit 216 may activate the first selection signal ACT_EN and deactivate the second selection signal REF_EN, in response to a global reset signal RSTB which is activated to a logic low level during initialization. In more detail, the latch output circuit 416 may include an SR latch 416A and a buffer 416B. The latch output circuit 416 may have substantially the same configuration as the latch output circuit 216 of FIG. 4.

With the above configuration, when the second test mode signal TM2 is at the first logic level, the selection control circuit 410 may activate the second selection signal REF_EN and deactivate the first selection signal ACT_EN, according to the first refresh section signal REF_BK. When the second test mode signal TM2 is at the second logic level, the selection control circuit 410 may activate the second selection signal REF_EN and deactivate the first selection signal ACT_EN according to the second refresh section signal REF_ALLBK. Further, when the bank selection signal RACTD_CTRL is activated, the selection control circuit 410 may deactivate the second selection signal REF_EN and activate the first selection signal ACT_EN.

Hereinafter, an operation of the memory device 300 according to an embodiment of the present disclosure will be described with reference to FIGS. 8 to 11B.

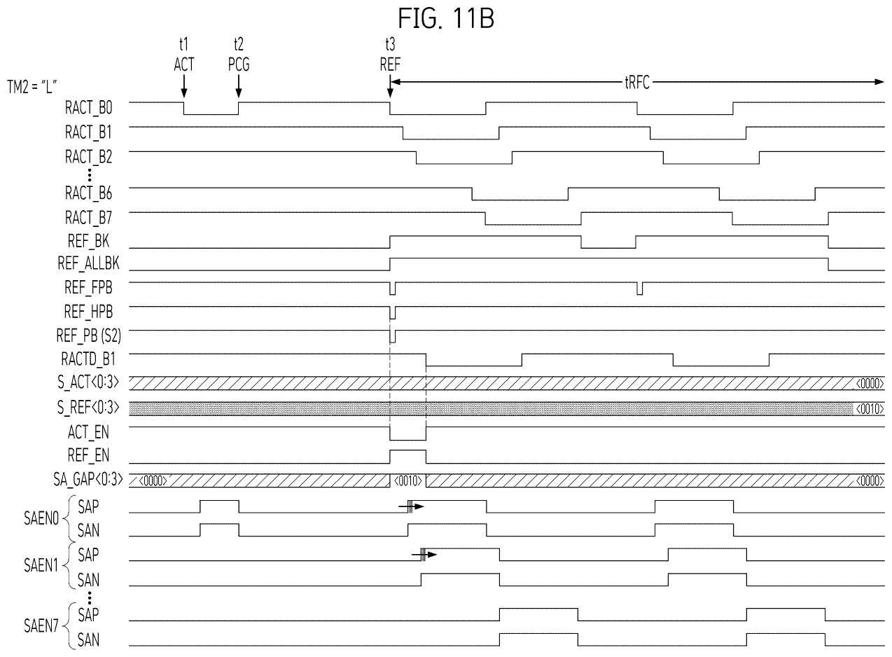

FIGS. 11A and 11B are timing diagrams for describing an operation of the memory device 300 of FIG. 8, according to an embodiment of the present disclosure. In FIGS. 11A and 11B, a case in which the first to eighth banks are refreshed twice during a refresh operation according to one refresh command will be described as an example.

Referring to FIG. 11A, the operation of the memory device 300 when the second test mode signal TM2 is at the first logic level (i.e., a logic high level) is shown. Through a test operation, first voltage information S_ACT<0:3> of “0000” is set and stored, and second voltage information S_REF<0:3> “0010” is set and stored. During initialization, according to a global reset signal RSTB, a first selection signal ACT_EN may be activated to a logic high level, and a second selection signal REF_EN may be deactivated to a logic low level.

At a time point t1, an active command ACT and a bank address BKADD designating a bank (e.g., a first bank) to be activated may be input from an external device (e.g., a memory controller). Accordingly, an active operation may be performed on the first bank.

At a time point t2, when a precharge command PCG is input from the memory controller, a precharge operation may be performed on the first bank.

At a time point t3, a refresh command REF indicating an all-bank refresh operation may be input from the memory controller. In this case, a first test mode signal TM1 for selecting the second bank is set.

The refresh control circuit 372 may control a refresh operation for refreshing all of the first to eighth banks to be performed twice during a refresh cycle tRFC according to the refresh command REF. In addition, the refresh control circuit 372 may generate a first refresh section signal REF_BK that stays activated each time a refresh operation is performed once for all banks, and generate a second refresh section signal REF_ALLBK that stays activated while a refresh operation is performed twice for all banks.

The selection control circuit 410 may receive a second delayed bank active signal RACTD_B1 as the bank selection signal RACTD_CTRL according to the first test mode signal TM1, and output, as a set signal REF_PB, the first refresh section signal REF_BK according to the second test mode signal TM2. The selection control circuit 410 may activate the second selection signal REF_EN and deactivate the first selection signal ACT_EN according to a falling edge of the set signal REF_PB. Also, the selection control circuit 410 may deactivate the second selection signal REF_EN and activate the first selection signal ACT_EN according to a falling edge of the bank selection signal RACTD_CTRL. The selection circuit 420 may output target voltage information SA_GAP<0:3> of “0000” corresponding to the first voltage information S_ACT<0:3> during an activation section of the first selection signal ACT_EN, and output the target voltage information SA_GAP<0:3> of “0010” corresponding to the second voltage information S_REF<0:3> during an activation section of the second selection signal REF_EN.

The control signal generation circuit 34 may output first to eighth sensing control signals SAEN_B0 to SAEN_B7 to the first to eighth bank sense amplifier circuits 330_0 to 330_7, respectively, by adjusting activation timings of the first to eighth sensing control signals SAEN_B0 to SAEN_B7 according to the target voltage information SA_GAP<0:3>. For example, for the first and second banks, the control signal generation circuit 394 may delay the activation timing of a pull-up control signal SAP of each of the first and second sensing control signals SAEN_B0 and SAEN_B1 to a first delay value according to the target voltage information SA_GAP<0:3> of “0010”. Furthermore, for the third to eighth banks, the control signal generation circuit 394 may delay the activation timing of the pull-up control signal SAP of each of the third to eighth sensing control signals SAEN_B2 to SAEN_B7 to a second delay value different from the first delay value, according to the target voltage information SA_GAP<0:3> of “0000”.

Accordingly, for each refresh operation, the first and second bank sense amplifier circuits 330_0, 330_1 may sense and amplify the voltage difference between the bit lines BLT and BLB at a sensing timing that is different from the third to eighth bank sense amplifier circuits 330_2 to 330_7.

Referring to FIG. 11B, the operation of the memory device 300 when the second test mode signal TM2 is at the second logic level (i.e., a logic low level) is shown.

At a time of t3, the refresh control circuit 372 may control a refresh operation for refreshing all of the first to eighth banks to be performed twice according to the refresh command REF. In addition, the refresh control circuit 372 may generate a first refresh section signal REF_BK that stays activated each time a refresh operation is performed once for all banks, and generate a second refresh section signal REF_ALLBK that stays activated while a refresh operation is performed twice for all banks.

The selection control circuit 410 may receive the second delayed bank active signal RACTD_B1 as the bank selection signal RACTD_CTRL according to the first test mode signal TM1, and output, as the set signal REF_PB, the second refresh section signal REF_ALLBK according to the second test mode signal TM2. That is, unlike FIG. 11A, the selection control circuit 410 may output the set signal REF_PB that is pulsed only in a first refresh operation among two refresh operations. Accordingly, only in the refresh operation that is performed first among the two refresh operations, the first and second bank sense amplifier circuits 330_0 and 130_1 may sense and amplify a voltage difference between the bit lines BLT and BLB at a sensing timing that is adjusted differently from the third to eighth bank sense amplifier circuits 330_2 to 330_7.

Moreover, a physical arrangement of banks and an order of the banks in which an actual all-bank refresh operation is performed may be different. For example, when the first to fourth banks are divided and arranged as a lower bank group and the fifth to eighth banks are divided and arranged as an upper bank group, during an all-bank refresh operation, the first and fifth banks are simultaneously refreshed, the second and sixth banks are simultaneously refreshed, and the fourth and eighth banks may be simultaneously refreshed. In an embodiment of the present disclosure, regardless of the physical arrangement of the banks, sensing timings for the banks (e.g., the first and fifth banks) that perform a refresh operation under an initial voltage condition may be independently adjusted, different from the remaining banks that perform a refresh operation under a subsequent voltage condition. Accordingly, it is possible to improve the accuracy of data sensing by maintaining the sensing margin for each of the banks uniformly during the all-bank refresh operation. Accordingly, it is possible to improve the performance and reliability of the memory device.

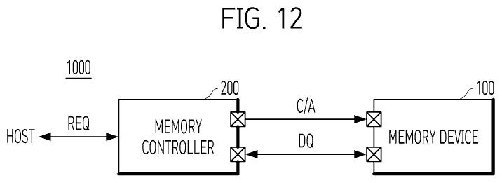

FIG. 12 is a block diagram illustrating a memory system 1000 according to an embodiment of the present disclosure.

Referring to FIG. 12, the memory system 1000 may include a memory device 100 and a memory controller 200.

The memory controller 200 may control an overall operation of the memory system 1000 and control an overall data exchange between a host and the memory device 100. The memory controller 200 may generate a command/address signal C/A in response to a request REQ from the host and provide the command/address signal C/A to the memory device 100. According to an embodiment, the memory controller 200 may provide a clock together with a command/address signal C/A to the memory device 100. The memory controller 200 may provide data DQ corresponding to a request REQ provided from the host to the memory device 100. The memory controller 200 may provide data DQ read from the memory device 100 to the host. The command/address signal C/A provided by the memory controller 200 to the memory device 100 may include an active command ACT, a precharge command PCG, a read command RD, a write command WT, and a refresh command REF.

The memory device 100 may have substantially the same configuration as the memory device 100 of FIG. 1. The memory device 100 may include first to n-th banks, where n is a positive integer of 2 or more, a storage circuit configured to store first voltage information representing a voltage condition during an active operation, and second voltage information representing a voltage condition during a refresh operation, and a sensing control circuit configured to select one of the first voltage information and the second voltage information according to a refresh section signal and a bank selection signal designating one of the first to n-th banks, and independently control a sensing timing for each of the first to n-th banks based on the selected voltage information.

In this case, when the refresh section signal is activated, the sensing control circuit may adjust the sensing timings for the first to k-th banks, where k is an integer equal to or less than n, based on the second voltage information, and adjust the sensing timings for the (k+1)-th to n-th banks based on the first voltage information, according to the bank selection signal designating the k-th bank of the first to n-th banks. The refresh operation may include an all-bank refresh operation of refreshing all of the first to n-th banks according to a refresh command, and the memory device 100 may further include a refresh control circuit configured to generate a refresh section signal activated during the all-bank refresh operation. Furthermore, the memory device 100 may include an active control circuit configured to generate first to n-th bank active signals for sequentially activating the first to n-th banks according to a refresh command, and generating delayed bank active signals by delaying the first to n-th bank active signals. The timing control circuit may receive, as the bank selection signal, a delayed bank active signal selected according to a test mode signal from among the delayed bank active signals.

Various embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the present disclosure and the following claims.

For example, for the logic gates and transistors provided as examples in the above-described embodiments, different positions and types may be implemented depending on the polarity of the input signal.

What is claimed is:

1. A memory device comprising:
first to n-th banks, where n is a positive integer of 2 or more;
a storage circuit configured to store first voltage information representing a voltage condition during an active operation and second voltage information representing a voltage condition during a refresh operation; and
a sensing control circuit configured to select one of the first voltage information and the second voltage information according to a refresh section signal and a bank selection signal designating a k-th bank, where k is an integer equal to or less than n, among the first to n-th banks, and control a sensing timing for each of the first to n-th banks based on the selected voltage information.

2. The memory device of claim 1, wherein the sensing control circuit is configured to:
according to the bank selection signal when the refresh section signal is activated, adjust the sensing timings for the first to k-th banks based on the second voltage information, and adjust the sensing timings for the (k+1)-th to n-th banks based on the first voltage information.

3. The memory device of claim 1, wherein the refresh operation includes an all-bank refresh operation of refreshing all of the first to n-th banks according to a refresh command.

4. The memory device of claim 3, further comprising:
a refresh control circuit configured to generate the refresh section signal activated during the all-bank refresh operation.

5. The memory device of claim 1, wherein the sensing control circuit includes:
a timing control circuit configured to output, as target voltage information, voltage information selected according to the refresh section signal and the bank selection signal from among the first voltage information and the second voltage information; and
a control signal generation circuit configured to generate first to n-th sensing control signals according to first to n-th bank active signals while adjusting activation timings of the first to n-th sensing control signals according to the target voltage information.

6. The memory device of claim 5,
wherein each of the first to n-th sensing control signals includes a pull-up control signal and a pull-down control signal, and
further comprising:
first to n-th bank sense amplifier circuits respectively corresponding to the first to n-th banks and each configured to amplify and sense data of bit lines of a corresponding bank by receiving a pull-up voltage according to the pull-up control signal of a corresponding sensing control signal and receive a pull-down voltage according to the pull-down control signal of the corresponding sensing control signal.

7. The memory device of claim 5, further comprising:
an active control circuit configured to generate the first to n-th bank active signals for sequentially activating the first to n-th banks according to a refresh command, and generate first to n-th delayed bank active signals by delaying the first to n-th bank active signals,
wherein the timing control circuit receives, as the bank selection signal, a delayed bank active signal selected according to a test mode signal from among the delayed bank active signals.

8. The memory device of claim 5, wherein the timing control circuit includes:
a selection control circuit configured to activate a first selection signal or a second selection signal according to the refresh section signal and the bank selection signal; and
a selection circuit configured to output, as the target voltage information, voltage information selected according to the first selection signal and the second selection signal from among the first voltage information and the second voltage information.

9. The memory device of claim 8, wherein the selection control circuit includes:
a pulse generator configured to generate a set signal that is pulsing when the refresh section signal is activated; and
a latch output circuit configured to generate the second selection signal activated according to the set signal and deactivated according to the bank selection signal and generate the first selection signal by inverting the second selection signal.

10. The memory device of claim 9, wherein the selection control circuit further includes:
a target bank selector configured to receive, as the bank selection signal, a delayed bank active signal selected according to a test mode signal from among delayed bank active signals.

11. The memory device of claim 1, wherein the storage circuit includes:
a first storage configured to detect and store, as the first voltage information, an optimal voltage condition during the active operation through a test operation; and
a second storage configured to detect and store, as the second voltage information, an optimal voltage condition during the refresh operation through the test operation.

12. A memory device comprising:
first to n-th banks, where n is a positive integer of 2 or more;
a refresh control circuit configured to control at least two refresh operations each for refreshing all of the first to n-th banks and generate a first refresh section signal staying activated during each of the refresh operations and a second refresh section signal staying activated until all of the refresh operations are completed, according to a refresh command; and
a sensing control circuit configured to select one of first voltage information and second voltage information according to the first and second refresh section signals and a bank selection signal designating a k-th bank, where k is an integer equal to or less than n, among the first to n-th banks and control a sensing timing for each of the first to n-th banks based on the selected voltage information.

13. The memory device of claim 12, wherein the sensing control circuit is configured to:
select one of the first and second refresh section signals, and
according to the bank selection signal when the selected refresh section signal is activated, adjust the sensing timings for the first to k-th banks based on the second voltage information, and adjust the sensing timings for the (k+1)-th to n-th banks based on the first voltage information.

14. The memory device of claim 12, wherein the sensing control circuit includes:
a selection control circuit configured to activate a first selection signal or a second selection signal according to the first and second refresh section signals and the bank selection signal;
a selection circuit configured to output, as target voltage information, voltage information selected according to the first selection signal and the second selection signal from among the first voltage information and the second voltage information; and
a control signal generation circuit configured to generate first to n-th sensing control signals according to first to n-th bank active signals while adjusting activation timings of the first to n-th sensing control signals according to the target voltage information.

15. The memory device of claim 14, wherein the selection control circuit includes:
a first pulse generator configured to generate a first pulse signal pulsing when the first refresh section signal is activated;
a second pulse generator configured to generate a second pulse signal pulsing when the second refresh section signal is activated;
a pulse selector configured to output, as a set signal, one of the first pulse signal and the second pulse signal according to a second test mode signal; and
a latch output circuit configured to generate the second selection signal activated according to the set signal and deactivated according to the bank selection signal and generate the first selection signal by inverting the second selection signal.

16. The memory device of claim 15, wherein the selection control circuit further includes:
a target bank selector configured to receive, as the bank selection signal, a delayed bank active signal selected according to a first test mode signal, from among delayed bank active signals.

17. The memory device of claim 12, wherein the storage circuit includes:
a first storage configured to detect and store, as the first voltage information, an optimal voltage condition during the active operation through a test operation; and
a second storage configured to detect and store, as the second voltage information, an optimal voltage condition during the refresh operations through the test operation.

18. An operating method of a memory device, the operating method comprising:
receiving a refresh command;
activating a refresh section signal and sequentially activating first to n-th bank active signals, where n is a positive integer of 2 or more, according to the refresh command; and
refreshing the first to n-th banks according to the first to n-th bank active signals, while selecting one of first voltage information and second voltage information according to the refresh section signal and a bank selection signal designating a k-th bank, where k is an integer equal to or less than n, among the first to n-th banks and controlling a sensing timing for each of the first to n-th banks based on the selected voltage information.

19. The operating method of claim 18, further comprising:
storing first voltage information representing a voltage condition during an active operation and second voltage information representing a voltage condition during a refresh operation.

20. The operating method of claim 18, wherein controlling the sensing timing for each of the first to n-th banks includes:
according to the bank selection signal when the refresh section signal is activated, adjusting the sensing timings for the first to k-th banks based on the second voltage information, and adjusting the sensing timings for the (k+1)-th to n-th banks based on the first voltage information.

21. The operating method of claim 18, further comprising:
generating first to n-th delayed bank active signals by delaying the first to n-th bank active signals; and
outputting, as the bank selection signal, a delayed bank active signal selected according to a test mode signal, from among the delayed bank active signals.

22. An operating method of a memory device, the operating method comprising:
receiving a refresh command;
performing at least two refresh operations each of refreshing all of first to n-th banks, where n is a positive integer of 2 or more, according to the refresh command;
generating, according to the refresh command, a first refresh section signal staying activated during each of the refresh operations and a second refresh section signal staying activated until all of the refresh operations are completed; and
selecting one of first voltage information and second voltage information according to the first and second refresh section signals and a bank selection signal designating a k-th bank, where k is an integer equal to or less than n, among the first to n-th banks and controlling a sensing timing for each of the first to n-th banks based on the selected voltage information.

23. The operating method of claim 22, further comprising:
storing first voltage information representing a voltage condition during an active operation and second voltage information representing a voltage condition during a refresh operation.

24. The operating method of claim 22, further comprising:
generating first to n-th delayed bank active signals by delaying the first to n-th bank active signals; and
outputting, as the bank selection signal, a delayed bank active signal selected according to a first test mode signal from among the delayed bank active signals.

25. The operating method of claim 22, wherein controlling the sensing timing for each of the first to n-th banks includes:
selecting one of the first and second refresh section signals, and
according to the bank selection signal when the selected refresh section signal is activated, adjusting the sensing timings for the first to k-th banks based on the second voltage information, and adjusting the sensing timings for the (k+1)-th to n-th banks based on the first voltage information.
